(19) United States
(12) Patent Application Publication
(10) Pub. No.: US 2022/0310776 A1
(43) Pub. Date: Sep. 29, 2022

(54) INTEGRATED PLATFORM FOR TIN PVD AND HIGH-K ALD FOR BEOL MIM CAPACITOR

(71) Applicant: Applied Materials, Inc., Santa Clara, CA (US)

(72) Inventors: Keith Tatseun WONG, Mountain View, CA (US); Srinivas D. NEMANI, Saratoga, CA (US); Ellie YIEH, San Jose, CA (US); Tony P. CHIANG, Los Gatos, CA (US)

(21) Appl. No.: 17/210,130

(22) Filed: Mar. 23, 2021

(51) Int. Cl. H01L 49/02; C23C 16/40; C23C 14/06; C23C 16/455; C23C 28/04

(52) U.S. Cl. CPC H01L 28/60; C23C 16/403; C23C 14/0641; C23C 16/45527; C23C 28/042

(57) ABSTRACT

Methods and apparatus for processing a substrate are provided herein. For example, a method of processing a substrate in an integrated tool comprising a physical vapor deposition chamber and a thermal atomic layer deposition chamber comprises depositing, in the physical vapor deposition chamber, a bottom layer of titanium nitride on the substrate to a thickness of about 10 nm to about 80 nm, transferring, without vacuum break, the substrate from the physical vapor deposition chamber to the thermal atomic layer deposition chamber for depositing a nanolaminate layer of high-k material atop the bottom layer of titanium nitride to a thickness of about 2 nm to about 10 nm, and transferring, without vacuum break, the substrate from the thermal atomic layer deposition chamber to the physical vapor deposition chamber for depositing a top layer of titanium nitride atop the nanolaminate layer of high-k material to a thickness of about 10 nm to about 80 nm.

### FIELD

Embodiments of the present disclosure generally relate to a methods and apparatus for processing a substrate, and more particularly, to an integrated platform for titanium nitride (TiN) physical vapor deposition and high-k atomic layer deposition for back-end-of-line (BEOL) metal-insulator-metal (MIM) capacitor.

### BACKGROUND

A semiconductor memory device generally comprises a plurality of memory cells which are used to store a large quantity of information. Each memory cell includes a capacitor for storing electric charge and a corresponding field effect transistor for opening and closing charging and discharging passages of the capacitor. An example of a capacitor used in a semiconductor memory device is a metal-insulator-metal (MIM) capacitor (e.g., 2D MIM capacitor or 3D MIM capacitor). MIM capacitors are, typically, formed in successive metal interconnect layers of the back end of the line (BEOL) stage of the chip fabrication, the fabrication stage in which multiple metal interconnect layers interconnect the components and nodes, including components formed in the substrate during the front end of the line (FEOL) processing. During MIM capacitor fabrication, oxide can sometimes form on an interface of the metal layers due to air exposure. For example, when the metal layer is titanium, titanium oxide (TiO₂) can form on the interface of the Ti layer, which can contribute to high leakage and low capacitance.

### SUMMARY

Methods and apparatus for processing a substrate are provided herein. In some embodiments, a method of processing a substrate in an integrated tool comprising a physical vapor deposition chamber and a thermal atomic layer deposition chamber includes depositing, in the physical vapor deposition chamber, a bottom layer of titanium nitride on the substrate to a thickness of about 10 nm to about 80 nm, transferring, without vacuum break, the substrate from the physical vapor deposition chamber to the thermal atomic layer deposition chamber for depositing a nanolaminate layer of high-k material atop the bottom layer of titanium nitride to a thickness of about 2 nm to about 10 nm, and transferring, without vacuum break, the substrate from the thermal atomic layer deposition chamber to the physical vapor deposition chamber for depositing a top layer of titanium nitride atop the nanolaminate layer of high-k material to a thickness of about 10 nm to about 80 nm.

In accordance with at least some embodiments, a non-transitory computer readable storage medium has stored thereon instructions that when executed by a processor perform a method of processing a substrate in an integrated tool comprising a physical vapor deposition chamber and a thermal atomic layer deposition chamber. The method includes depositing, in the physical vapor deposition chamber, a bottom layer of titanium nitride on the substrate to a thickness of about 10 nm to about 80 nm, transferring, without vacuum break, the substrate from the physical vapor deposition chamber to the thermal atomic layer deposition chamber for depositing a nanolaminate layer of high-k material atop the bottom layer of titanium nitride to a thickness of about 2 nm to about 10 nm, and transferring, without vacuum break, the substrate from the thermal atomic layer deposition chamber to the physical vapor deposition chamber for depositing a top layer of titanium nitride atop the nanolaminate layer of high-k material to a thickness of about 10 nm to about 80 nm.

In accordance with at least some embodiments, an integrated tool for processing a substrate includes a vacuum substrate transfer chamber, a physical vapor deposition chamber coupled to the vacuum transfer chamber and configured to deposit one or more metal layers, a thermal atomic layer deposition chamber coupled to the vacuum transfer chamber and configured to receive the substrate from the physical vapor deposition chamber without vacuum break to deposit one or more nanolaminate layers, and a controller configured to deposit, in the physical vapor deposition chamber, a bottom layer of titanium nitride on the substrate to a thickness of about 10 nm to about 80 nm, transfer, without vacuum break, the substrate from the physical vapor deposition chamber to the thermal atomic layer deposition chamber for depositing a nanolaminate layer of high-k material atop a bottom layer of titanium nitride to a thickness of about 2 nm to about 10 nm, and transfer, without vacuum break, the substrate from the thermal atomic layer deposition chamber to the physical vapor deposition chamber for depositing a top layer of titanium nitride atop the nanolaminate layer of high-k material to a thickness of about 10 nm to about 80 nm.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a flowchart of a method for processing a substrate, in accordance with at least some embodiments of the disclosure.

FIG. 2 is a schematic diagram of an apparatus for processing a substrate, in accordance with at least some embodiments of the present disclosure.

FIG. 3 is a diagram of a substrate, in accordance with at least some embodiments of the present disclosure.

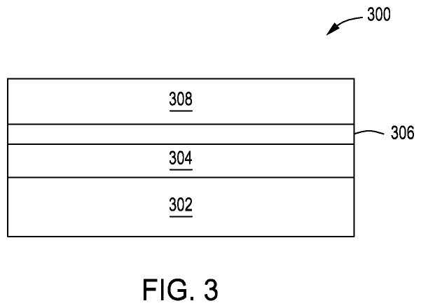

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods and apparatus for processing a substrate are described herein. For example, methods described herein use an integrated platform for titanium nitride (TiN) physical vapor deposition (PVD) and high-k atomic layer deposition (ALD) for BEOL MIM capacitor. In at least some embodiments, a TiN layer (film) is first deposited on a substrate in a PVD chamber, the substrate is then transferred, without air break, to an ALD chamber for depositing a layer of high-k material a top the TiN layer, and the substrate is then transferred back to the PVD for depositing a TiN layer (film) atop the high-k material. In at least some embodiments, prior to depositing the layer of high-k material, one or more pretreatment process gases and/or pretreatment ALD precursors can be used for pre-treatment of an interface between the TiN layer and the layer of high-k material. Unlike the conventional methods and apparatus described above, the methods and apparatus described herein provide a MIM capacitor with low leakage and high capacitance.

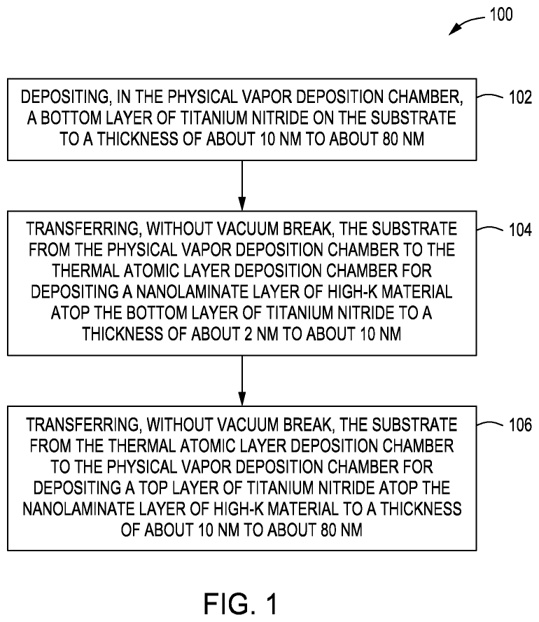

FIG. 1 is a flowchart of a method 100 for processing a substrate, in accordance with at least some embodiments of the disclosure. The method 100 may be performed in the tool 200 including any suitable process chambers configured for one or more of physical vapor deposition (PVD), chemical vapor deposition (CVD), such as plasma-enhanced CVD (PECVD) and/or atomic layer deposition (ALD), such as plasma-enhanced ALD (PEALD) or thermal ALD (e.g., no plasma formation). Exemplary processing systems that may be used to perform the inventive methods disclosed herein are commercially available from Applied Materials, Inc., of Santa Clara, Calif. Other process chambers, including those from other manufacturers, may also be suitably used in connection with the teachings provided herein.

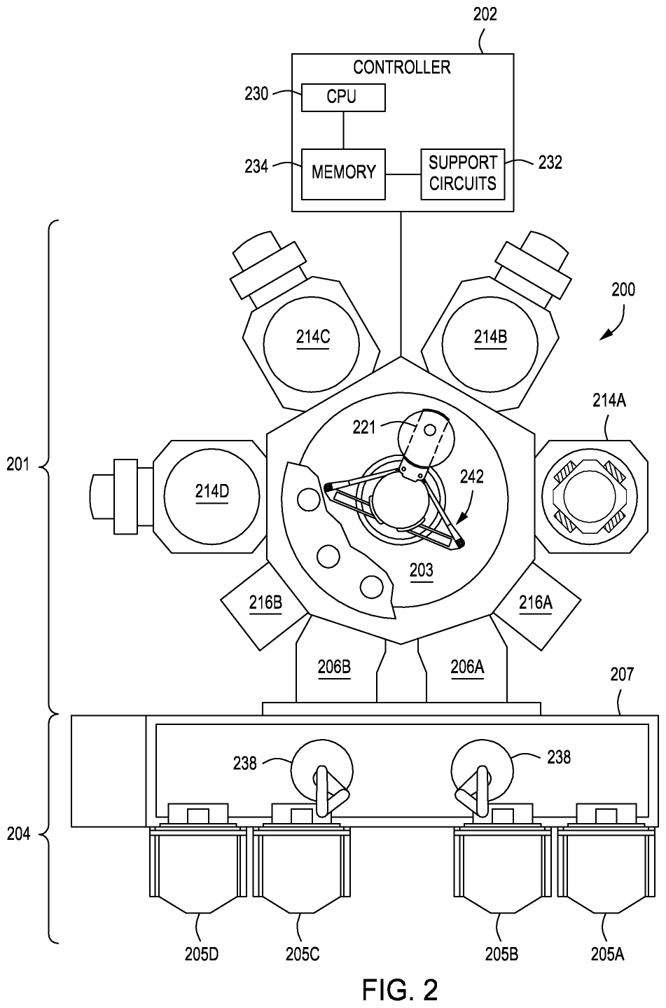

The tool 200 can be embodied in individual process chambers that may be provided in a standalone configuration or as part of a cluster tool, for example, an integrated described below with respect to FIG. 2. Examples of the integrated tool are available from Applied Materials, Inc., of Santa Clara, Calif. The methods described herein may be practiced using other cluster tools having suitable process chambers coupled thereto, or in other suitable process chambers. For example, in some embodiments, the inventive methods discussed above may be performed in an integrated tool such that there are limited or no vacuum breaks between processing steps. For example, reduced vacuum breaks may limit or prevent contamination (e.g., oxidation) of the titanium nitride layer or other portions of the substrate.

The integrated tool includes a processing platform 201 (vacuum-tight processing platform), a factory interface 204, and a system controller 202. The processing platform 201 comprises multiple process chambers, such as 214A, 214B, 214C, and 214D operatively coupled to a transfer chamber 203 (vacuum substrate transfer chamber). The factory interface 204 is operatively coupled to the transfer chamber 203 by one or more load lock chambers (two load lock chambers, such as 206A and 206B shown in FIG. 2).

In some embodiments, the factory interface 204 comprises a docking station 207, a factory interface robot 238 to facilitate the transfer of one or more semiconductor substrates (wafers). The docking station 207 is configured to accept one or more front opening unified pod (FOUP). Four FOUPS, such as 205A, 205B, 205C, and 205D are shown in the embodiment of FIG. 2. The factory interface robot 238 is configured to transfer the substrates from the factory interface 204 to the processing platform 201 through the load lock chambers, such as 206A and 206B. Each of the load lock chambers 206A and 206B have a first port coupled to the factory interface 204 and a second port coupled to the transfer chamber 203. The load lock chamber 206A and 206B are coupled to a pressure control system (not shown) which pumps down and vents the load lock chambers 206A and 206B to facilitate passing the substrates between the vacuum environment of the transfer chamber 203 and the substantially ambient (e.g., atmospheric) environment of the factory interface 204. The transfer chamber 203 has a vacuum robot 242 disposed within the transfer chamber 203. The vacuum robot 242 is capable of transferring substrates 221 between the load lock chamber 206A and 206B and the process chambers 214A, 214B, 214C, and 214D.

In some embodiments, the process chambers 214A, 214B, 214C, and 214D, are coupled to the transfer chamber 203. The process chambers 214A, 214B, 214C, and 214D comprise at least an ALD chamber, a CVD chamber, a PVD chamber, an e-beam deposition chamber, an electroplating, electroless (EEP) deposition chamber, a wet etch chamber, a dry etch chamber, an anneal chamber, and/or other chamber suitable for performing the methods described herein.

In some embodiments, one or more optional service chambers (shown as 216A and 216B) may be coupled to the transfer chamber 203. The service chambers 216A and 216B may be configured to perform other substrate processes, such as degassing, bonding, chemical mechanical polishing (CMP), wafer cleaving, etching, plasma dicing, orientation, substrate metrology, cool down and the like.

The system controller 202 controls the operation of the tool 200 using a direct control of the process chambers 214A, 214B, 214C, and 214D or alternatively, by controlling the computers (or controllers) associated with the process chambers 214A, 214B, 214C, and 214D and the tool 200. In operation, the system controller 202 enables data collection and feedback from the respective chambers and systems to optimize performance of the tool 200. The system controller 202 generally includes a central processing unit 230, a memory 234, and a support circuit 232. The central processing unit 230 may be any form of a general-purpose computer processor that can be used in an industrial setting. The support circuit 232 is conventionally coupled to the central processing unit 230 and may comprise a cache, clock circuits, input/output subsystems, power supplies, and the like. Software routines, such as processing methods as described above may be stored in the memory 234 (e.g., non-transitory computer readable storage medium having instructions stored thereon) and, when executed by the central processing unit 230, transform the central processing unit 230 into a system controller 202 (specific purpose computer). The software routines may also be stored and/or executed by a second controller (not shown) that is located remotely from the tool 200.

Continuing with reference to FIG. 1, the method 100 can be used to fabricate a BEOL MIM capacitor on one or more substrates. For example, in at least some embodiments, A substrate 300 can be a carrier substrate, which can be made from glass, a metal layer of one of a redistribution layer interposer (RDL) or a substrate interconnect, or at least one of a digital circuit, a dynamic random-access memory, or an integrated circuit (die), etc.

Initially, the substrate 300 may be loaded into one or more of the Four FOUPS, such as 205A, 205B, 205C, and 205D. For example, in at least some embodiments, the substrate 300 can be loaded into FOUP 205A.

Under control of the system controller 202, the method 100 includes, at 102, depositing, in a physical vapor deposition chamber, a bottom layer of titanium nitride on the substrate. For example, once loaded, the factory interface robot 238 can transfer the substrate 300 from the factory interface 204 to the processing platform 201 through, for example, the load lock chamber 206A. The vacuum robot 242 can transfer the substrate 300 from the load lock chamber 206A to and from one or more of the process chambers 214A-214D and/or the service chambers 216A and 216B. For example, the vacuum robot 242 can transfer the substrate 300 to the process chamber 214A to deposit a metal layer 304 (e.g., a bottom layer of titanium nitride) using one or more of the above-mentioned deposition processes. In at least some embodiments, the process chamber 214A can be configured to perform PVD (e.g., DC sputtering) to deposit the metal layer 304 on a base layer 302 (e.g., SiO₂, SiOC, SiN, SiON, low-k materials, such as SiOC:H, etc.).

At 102, PVD can be performed at a pressure of 1-200 mTorr, a DC power of about 10 kW to about 20 kW, and with one or more process gases, such as argon or nitrogen, at a flow rate of 100 sccm to about 500 sccm.

The metal layer 304 can be deposited to one or more suitable thicknesses. For example, in at least some embodiments, the metal layer 304 can have a thickness of about 10 nm to about 80 nm. In at least some embodiments, the metal layer 304 can have a thickness of about 30 nm to about 60 nm.

Next, at 104, the method 100 comprises transferring, without vacuum break, the substrate from the physical vapor deposition chamber to the thermal atomic layer deposition chamber for depositing a nanolaminate layer of high-k material atop metal layer 304 (e.g., the bottom layer of titanium nitride).

For example, after the metal layer 304 is deposited on the base layer 302 to a desired thickness, the vacuum robot 242 can transfer the substrate 300 from the process chamber 214A to the process chamber 214B. For example, the process chamber 214B can be configured to perform one or more ALD processes to deposit nanolaminate layer 306 of high-k material atop the metal layer 304. In at least some embodiments, the nanolaminate layer 306 can comprise at least one of Al₂O₃, HfO₂, Nb₂O₅, SiO₂, TiO₂, or ZrO₂. In at least some embodiments, the nanolaminate layer 306 can comprise AlZrOₓ, with Al/(Al+Zr) equal to about 5% to about 25%. In at least some embodiments, the nanolaminate layer 306 can comprise AlZrOₓ doped with less than 10% of at least one of HfO₂, SiO₂, Nb₂O₅, or TiO₂.

The nanolaminate layer 306 can be deposited to one or more suitable thicknesses. For example, in at least some embodiments, the nanolaminate layer 306 can have a thickness of about 2 nm to about 10 nm. In at least some embodiments, the metal layer 304 can have a thickness of about 6 nm. In at least some embodiments, the process parameters during ALD can comprise maintaining the substrate at a temperature of about 200° C. to about 400° C., maintaining a pressure within a processing volume of the process chamber 214B of about 1 Torr to about 20 Torr, and supplying one or more process gases (e.g., purge/carrier gas) such as, argon, helium, nitrogen (N₂) at a rate of about 500 sccm to about 8000 sccm.

Next, at 106, the method 100 comprises transferring, without vacuum break, the substrate from the thermal atomic layer deposition chamber to the physical vapor deposition chamber for depositing a top layer of titanium nitride atop the nanolaminate layer of high-k material. For example, after the nanolaminate layer 306 is deposited on the base layer 302 to a desired thickness, the vacuum robot 242 can transfer the substrate 300 from the process chamber 214A to the process chamber 214B. For example, in at least some embodiments, a metal layer 308 (e.g., a top layer of titanium nitride) can be deposited atop the nanolaminate layer 306 (e.g., under the same process conditions as the metal layer 304). Additionally, the metal layer 308 can be deposited to one or more suitable thicknesses. For example, in at least some embodiments, the metal layer 308 can have a thickness of about 10 nm to about 80 nm. In at least some embodiments, the metal layer 304 can have a thickness of about 30 nm to about 60 nm. In at least some embodiments, the thickness of the metal layer 304 can be the same as the thickness of the metal layer 308. Alternatively, the thickness of the metal layer 304 can be different from the thickness of the metal layer 308.

In at least some embodiments, a pretreatment of the metal layer 304 can be performed immediately after vacuum transfer to the process chamber 214B for ALD, e.g., to form metal oxide (e.g., TiO₂) interface on the metal layer. For example, prior to depositing the nanolaminate layer of high-k material atop the bottom layer of titanium nitride, the method 100 can comprise performing one or more oxidizing treatments on at least one of a top surface of the metal layer 304 (e.g., the bottom layer of titanium nitride) or a bottom surface of the metal layer 308 (e.g., the top layer of titanium nitride). The one or more oxidizing treatments can be performed for about 0.1 s to about 60 s and comprise supplying oxidizing gas comprising at least one of O₂, O₃, or H₂O(g). For example, in at least some embodiments, the oxidizing gas can comprise 03. Additionally, during the one or more oxidizing treatments, the method 100 can comprise heating the substrate to a temperature of about 200° C. to about 400° C. For example, in at least some embodiments, the substrate can be heated at about 300° C. During the one or more oxidizing treatments, the method 100 can comprise maintaining a pressure of a processing volume of the thermal atomic layer deposition chamber at about 1 Torr to about 20 Torr. For example, in at least some embodiments, the thermal atomic layer deposition chamber can be maintained at about 10 Torr. During the one or more oxidizing treatments, the method 100 can comprise supplying a purge or carrier gas comprising at least one of Ar, N₂, He at a flow rate of about 0 sccm to about 8000 sccm. For example, in at least some embodiments, Ar can be supplied at about 4000 sccm.

Alternatively, pretreatment of the metal layer 304 can comprise supplying one or more metal precursors to form an interface without an oxidizing agent. For example, prior to depositing the nanolaminate layer of high-k material atop the bottom layer of titanium nitride, the method 100 can comprise supplying one or more ALD metal precursors (e.g., to form metal interface without oxide layer) comprising at least one of Al (e.g., Al(CH₃)₃, Al(OⁱPr)₃, Al(NEt₂)₃, Al(NMe₂)₃, AlCl₃), Hf (e.g., Hf(NMe₂)⁴, Hf(NE^{t}₂)₄, Hf(NEtMe)₄, Hf(Cp)(NMe₂)₃, Hf(CpMe)(NMe₂)₃, Hf(CpMe)₂Me₂, Hf(OⁱPr)⁴, Hf(O^{t}Bu)₄, HfCl₄, Nb (e.g., Nb(N^{t}Bu)(NE^{t}₂)₃, Nb(N^{t}Bu)(NEtMe)₃, Nb(OE^{t})₅, Si (e.g., Si₂Cl₆, SiCl₂H₂, SiCl₄, SiH(NMe₂)₃, SiH₂(NE^{t}₂)₂, Ti (e.g., Ti(CpMe₅)(OMe)₃, Ti(E^{t}Cp)(NMe₂)₃, Ti(NE^{t}₂)₄, Ti(NMe₂)₄, Ti(NMeE^{t})₄, Ti(OⁱPr)₄, TiCl₄), or Zr (e.g., Zr(NMe₂)₄, Zr(NE^{t}₂)₄, Zr(NE^{t}Me)₄, ZrCp(NMe₂)₃, ZrCp²Me², Zr(Cp²CMe²)Me₂, Zr(CpE^{t})(NMe₂)₃, Zr(OⁱPr)₄, Zr(O^{t}Bu)₄, ZrCl₄. Pretreatment of the metal layer using the metal precursor can performed for about 0.1 s to about 20 s. Additionally, during pretreatment of the metal layer using the metal precursor, the method 100 can comprise heating the substrate to a temperature of about 200° C. to about 400° C. (e.g., to about 300° C.), maintaining a pressure of a processing volume of the thermal atomic layer deposition chamber at about 1 Torr to about 20 Torr (e.g., 10 Torr), and supplying a purge or carrier gas comprising at least one of Ar, N₂, or He at a flow rate of about 5000 sccm to about 8000 sccm (e.g., N₂ at 6500 sccm).

After 106, 102-106 (and the oxidizing pretreatment or the metal precursor pretreatment) can be repeated to form as many MIM layers as required (e.g., MIMIMIMIM . . . ).

While the foregoing is directed to embodiments of the present disclosure, other and further embodiments of the disclosure may be devised without departing from the basic scope thereof.

1. A method of processing a substrate in an integrated tool comprising a physical vapor deposition chamber and a thermal atomic layer deposition chamber, the method comprising:
depositing, in the physical vapor deposition chamber, a bottom layer of titanium nitride on the substrate to a thickness of about 10 nm to about 80 nm;
transferring, without vacuum break, the substrate from the physical vapor deposition chamber to the thermal atomic layer deposition chamber for depositing a nanolaminate layer of high-k material atop the bottom layer of titanium nitride to a thickness of about 2 nm to about 10 nm; and
transferring, without vacuum break, the substrate from the thermal atomic layer deposition chamber to the physical vapor deposition chamber for depositing a top layer of titanium nitride atop the nanolaminate layer of high-k material to a thickness of about 10 nm to about 80 nm.

2. The method of claim 1, further comprising depositing the bottom layer of titanium nitride and the top layer of titanium nitride to a thickness of about 30 nm to about 60 nm, and
depositing the nanolaminate layer of high-k material to a thickness of about 6 nm.

3. The method of claim 1, wherein the nanolaminate layer of high-k material comprises at least one of Al₂O₃, HfO₂, Nb₂O₅, SiO₂, TiO₂, or ZrO₂.

4. The method of claim 1, wherein the nanolaminate layer of high-k material comprises AlZrOₓ, with Al/(Al+Zr) equal to about 5% to about 25%.

5. The method of claim 1, wherein the nanolaminate layer of high-k material comprises AlZrOₓ doped with less than 10% of at least one of HfO₂, SiO₂, Nb₂O₅, or TiO₂.

6. The method of claim 1, wherein prior to depositing the nanolaminate layer of high-k material atop the bottom layer of titanium nitride, supplying a metal precursor comprising at least one of Al, Hf, Nb, Si, Ti, or Zr.

7. The method of claim 6, further comprising heating the substrate to a temperature of about 200° C. to about 400° C.

8. The method of claim 6, further comprising maintaining a pressure of a processing volume of the thermal atomic layer deposition chamber at about 1 Torr to about 20 Torr.

9. The method of claim 6, further comprising supplying a purge or carrier gas comprising at least one of Ar, N₂, or He at a flow rate of about 5000 sccm to about 8000 sccm.

10. The method of claim 6, wherein further comprising supplying the metal precursor for about 0.1 s to about 20 s.

11. The method of claim 1, wherein prior to depositing the nanolaminate layer of high-k material atop the bottom layer of titanium nitride, performing one or more oxidizing treatments on at least one of a top surface of the bottom layer of titanium nitride or a bottom surface of the top layer of titanium nitride.

12. The method of claim 11, further comprising supplying oxidizing gas comprising at least one of O₂, O₃, or H₂O(g).

13. The method of claim 11, further comprising heating the substrate to a temperature of about 200° C. to about 400° C.

14. The method of claim 11, further comprising maintaining a pressure of a processing volume of the thermal atomic layer deposition chamber at about 1 Torr to about 20 Torr.

15. The method of claim 11, further comprising supplying a purge or carrier gas comprising at least one of Ar, N₂, He at a flow rate of about 0 sccm to about 8000 sccm.

16. The integrated tool of claim 11, further comprising performing one or more oxidizing treatments for about 0.1 s to about 60 s.

17. A non-transitory computer readable storage medium having stored thereon instructions that when executed by a processor perform a method of processing a substrate in an integrated tool comprising a physical vapor deposition chamber and a thermal atomic layer deposition chamber, the method comprising:
depositing, in the physical vapor deposition chamber, a bottom layer of titanium nitride on the substrate to a thickness of about 10 nm to about 80 nm;
transferring, without vacuum break, the substrate from the physical vapor deposition chamber to the thermal atomic layer deposition chamber for depositing a nanolaminate layer of high-k material atop the bottom layer of titanium nitride to a thickness of about 2 nm to about 10 nm; and
transferring, without vacuum break, the substrate from the thermal atomic layer deposition chamber to the physical vapor deposition chamber for depositing a top layer of titanium nitride atop the nanolaminate layer of high-k material to a thickness of about 10 nm to about 80 nm.

18. The non-transitory computer readable storage medium of claim 17, further comprising depositing the bottom layer of titanium nitride and the top layer of titanium nitride to a thickness of about 30 nm to about 60 nm, and
depositing the nanolaminate layer of high-k material to a thickness of about 6 nm.

19. The non-transitory computer readable storage medium of claim 17, wherein the nanolaminate layer of high-k material comprises at least one of Al₂O₃, HfO₂, Nb₂O₅, SiO₂, TiO₂, or ZrO₂.

20. An integrated tool for processing a substrate, comprising
a vacuum substrate transfer chamber;
a physical vapor deposition chamber coupled to the vacuum transfer chamber and configured to deposit one or more metal layers;
a thermal atomic layer deposition chamber coupled to the vacuum transfer chamber and configured to receive the substrate from the physical vapor deposition chamber without vacuum break to deposit one or more nanolaminate layers; and
a controller configured to:
deposit, in the physical vapor deposition chamber, a bottom layer of titanium nitride on the substrate to a thickness of about 10 nm to about 80 nm;
transfer, without vacuum break, the substrate from the physical vapor deposition chamber to the thermal atomic layer deposition chamber for depositing a nanolaminate layer of high-k material atop a bottom layer of titanium nitride to a thickness of about 2 nm to about 10 nm; and
transfer, without vacuum break, the substrate from the thermal atomic layer deposition chamber to the physical vapor deposition chamber for depositing a top layer of titanium nitride atop the nanolaminate layer of high-k material to a thickness of about 10 nm to about 80 nm.
